(19) United States
(12) Patent Application Publication
(10) Pub. No.: US 2024/0215402 A1
(43) Pub. Date: Jun. 27, 2024

(54) DISPLAY SUBSTRATE, MANUFACTURING METHOD, AND DISPLAY DEVICE

(71) Applicant: BOE Technology Group Co., Ltd., Beijing (CN)

(72) Inventors: Can ZHANG, Beijing (CN); Xianqin MENG, Beijing (CN); Xiaochuan CHEN, Beijing (CN)

(21) Appl. No.: 17/913,787

(22) PCT Filed: Nov. 12, 2021
(86) PCT No.: PCT/CN2021/130335

§ 371 Date: Sep. 22, 2022

(30) Foreign Application Priority Data
May 24, 2021 (CN) CN2021105644363

(51) Int. Cl. H10K 59/80; H10K 59/12

(52) U.S. Cl. CPC H10K 59/876; H10K 59/1201

(57) ABSTRACT

The present disclosure provides a display substrate, a manufacturing method and a display device. The display substrate includes a base substrate and pixel units arranged in an array form on the base substrate. The base substrate includes a pixel circuitry formed on a substrate. Each pixel unit includes: a first electrode, a light-emitting layer, and a second electrode. The display substrate further includes a reflection layer between the first electrode and the base substrate, the first electrode is insulated from the reflection layer, and the first electrode is coupled to the pixel circuitry through a via hole penetrating through the reflection layer.

### CROSS-REFERENCE TO RELATED APPLICATION

This application claims a priority of the Chinese Patent Application No. 202110564436.3 filed on May 24, 2021, the entire contents of which are hereby incorporated by reference.

### TECHNICAL FIELD

The present disclosure relates to the field of display technology, in particular to a display substrate, a manufacturing method thereof, and a display device.

### BACKGROUND

Organic Light-Emitting Diode (OLED) element has become a most promising next-generation display technology due to such advantages as being thin and light, a wide viewing angle, self-luminescence, a continuously-adjustable color, low cost, fast response, a low power consumption, a low driving voltage, a wide operating temperature range, a simple manufacture process, high luminous efficiency and being flexible.

As a basic structure, the OLED element includes a cathode, an anode and an organic electroluminescent material between the cathode and the anode. One of the cathode and the anode of the OLED element must be transparent/translucent in a visible region. After a biased voltage has been applied to the OLED element, electrons and holes are injected into a light-emitting layer from the cathode and the anode respectively, and form excitons, i.e., electrons in an excited state, in the light-emitting layer. The excitons recombine in the light-emitting layer to release energy in the form of light.

### SUMMARY

An object of the present disclosure is to provide a display substrate, a manufacturing method thereof and a display device, so as to improve the luminous efficiency of the display device.

In order to solve the above technical problem, the present disclosure provides the following technical solutions.

In one aspect, the present disclosure provides in some embodiments a display substrate, including a base substrate and pixel units arranged in an array form on the base substrate. The base substrate includes a pixel circuitry formed on a substrate. Each pixel unit includes: a first electrode at a side of the base substrate; a light-emitting layer at a side of the first electrode away from the base substrate; and a second electrode at a side of the light-emitting layer away from the first electrode. The display substrate further includes a reflection layer between the first electrode and the base substrate, the first electrode is insulated from the reflection layer, and the first electrode is coupled to the pixel circuitry through a via hole penetrating through the reflection layer.

In a possible embodiment of the present disclosure, a minimum distance between the via holes of the adjacent pixel units is greater than a minimum distance between the first electrodes of the adjacent pixel units.

In a possible embodiment of the present disclosure, a minimum distance between an orthogonal projection of the via hole onto the first electrode and an edge of the first electrode is D1, a distance between the orthogonal projection of the via hole onto the first electrode and a center of the first electrode is D2, and D1 is less than D2.

In a possible embodiment of the present disclosure, the reflection layers of different pixel units are connected to form one piece.

In a possible embodiment of the present disclosure, a ratio of an area of the reflection layer to an area of a display region of the display substrate is greater than 90%.

In a possible embodiment of the present disclosure, the reflection layer is a conductive reflection layer, and an insulation layer is arranged between the conductive reflection layer and the first electrode.

In a possible embodiment of the present disclosure, the insulation layer has a thickness of 400 Å to 1000 Å.

In a possible embodiment of the present disclosure, the reflection layer is an insulation reflection layer, the insulation reflection layer includes at least one silicon dioxide film layer and at least one silicon nitride film layer, and the silicon dioxide film layers and the silicon nitride film layers are alternately laminated one on another.

In a possible embodiment of the present disclosure, the insulation reflection layer includes three silicon dioxide film layers and three silicon nitride film layers, and a reflectivity of the insulation reflection layer to light at a wavelength of 400 nm to 700 nm is greater than 80%.

In a possible embodiment of the present disclosure, the first electrode has a thickness of 500 Å to 1200 Å.

In another aspect, the present disclosure provides in some embodiments a display device including the above-mentioned display substrate and a driving circuitry for driving the display substrate.

In yet another aspect, the present disclosure provides in some embodiments a method for manufacturing a display substrate. The display substrate includes a base substrate and pixel units arranged in an array form on the base substrate, and the base substrate includes a pixel circuitry formed on a substrate. The method includes: providing the base substrate: forming a first electrode on the base substrate; forming a light-emitting layer at a side of the first electrode away from the base substrate: and forming a second electrode at a side of the light-emitting layer away from the first electrode. The method further includes forming a reflection layer between the first electrode and the base substrate, the first electrode is insulated from the reflection layer, and the first electrode is coupled to the pixel circuitry through a via hole penetrating through the reflection layer.

In a possible embodiment of the present disclosure, the reflection layer is a conductive reflection layer, and the method further includes forming an insulation layer between the conductive reflection layer and the first electrode.

In a possible embodiment of the present disclosure, the reflection layer is an insulation reflection layer, the forming the reflection layer includes forming at least one silicon dioxide film layer and at least one silicon nitride film layer, and the silicon dioxide film layers and the silicon nitride film layers are alternately laminated one on another.

### BRIEF DESCRIPTION OF THE DRAWINGS

FIG. 1 is a schematic view of a conventional display substrate:

FIG. 2 is a schematic view showing a size of a sub-pixel:

FIG. 3 is a schematic view showing a distance between patterns of adjacent film layers;

FIG. 4 is a schematic view showing light that does not participate in resonant cavity resonance;

FIG. 5 is a planar view of a display substrate according to one embodiment of the present disclosure;

FIGS. 6 and 7 are sectional views of the display substrate according to one embodiment of the present disclosure; and

FIG. 8 is a curve diagram of a reflectivity of an insulation reflection layer according to one embodiment of the present disclosure.

### REFERENCE SIGN LIST

01 base substrate
02 via hole
03 Ti layer
04 Ag or Al layer
05 ITO layer
06 light-emitting layer
07 reflection layer
08 first electrode
09 insulation layer
10 insulation reflection layer

### DETAILED DESCRIPTION

In order to make the objects, the technical solutions and the advantages of the present disclosure more apparent, the present disclosure will be described hereinafter in a clear and complete manner in conjunction with the drawings and embodiments.

A silicon-based OLED has such characteristics as small size and high resolution, and it is manufactured through a mature integrated circuit process to achieve the active addressing of pixels, so it is widely used in such fields as near-eye display, virtual reality and augmented reality.

The silicon-based OLED has an opaque silicon substrate, so a light-emitting element must use a top emission structure. Due to a resonant cavity effect, the luminous efficiency of the light-emitting element with the top emission structure is improved. The resonant cavity effect refers to a phenomenon of optical interference between two reflecting surfaces (or between a reflecting surface and a semi-reflecting surface), so a reflection electrode of the light-emitting element is crucial to the resonant cavity effect.

However, in the silicon-based OLED with high PPI (Pixels Per Inch), a size of the pixel is small, and an area of the reflection electrode is remarkably reduced, so the resonant cavity effect is adversely affected, and thereby the display brightness of the display substrate is deteriorated.

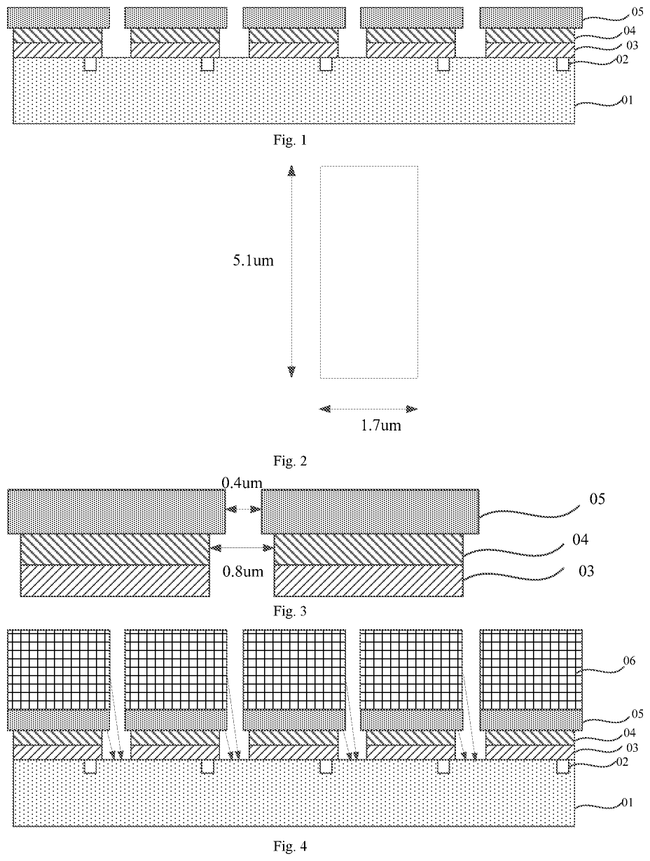

As shown in FIG. 1, a conventional silicon-based OLED display substrate includes a silicon base substrate 01, and a reflection electrode on the silicon base substrate 01. The reflection electrode includes film layers 03, 04 and 05, the film layer 03 is a Ti layer, the film layer 04 is an Ag or Al layer, and the film layer 05 is an ITO layer. The reflection electrode is coupled to a driving circuitry in the silicon base substrate through a via hole 02.

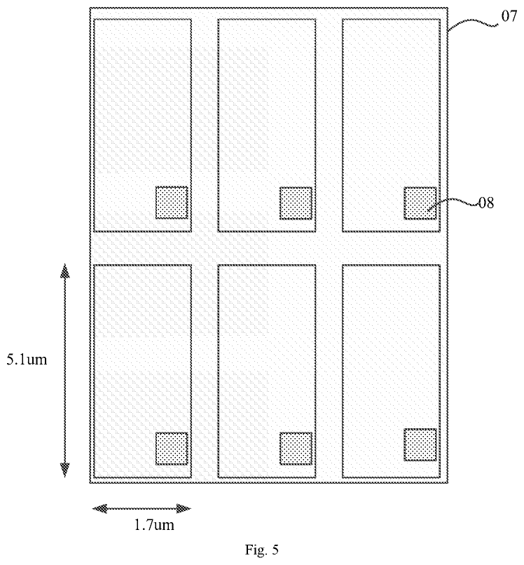

As shown in FIG. 2, for the silicon-based OLED display substrate with 5000 PPI, each sub-pixel has a length of 5.1 μm and a width of 1.7 μm. As shown in FIG. 3, in the reflection electrode, a distance between the film layers 04 of the adjacent sub-pixels is 0.8 μm, but a distance between the film layers 05 of the adjacent sub-pixels is 0.4 μm. The film layer 05 needs to protect the film layer 04 from being oxidized, so a size of the film layer 05 is larger than a size of the film layer 04. The film layer 04 in the reflection electrode functions as to reflect light, so an area of a reflective surface depends on an area of the film layer 04. The film layers 04 of the adjacent sub-pixels need to be spaced apart from each other by a certain distance, so the area of the reflective surface is relatively small. As shown in FIG. 4, a part of light emitted from the light-emitting layer 06 escapes from a gap between the adjacent sub-pixel film layers 04 without participating in the resonant cavity resonance, so a microcavity effect is deteriorated and thereby the luminous efficiency is reduced.

An object of the present disclosure is to provide a display substrate, a manufacturing method thereof and a display device, so as to improve the luminous efficiency of the display device.

The present disclosure provides in some embodiments a display substrate, which includes a base substrate and pixel units arranged in an array form on the base substrate. The base substrate includes a pixel circuitry formed on a substrate. Each pixel unit includes: a first electrode at a side of the base substrate; a light-emitting layer at a side of the first electrode away from the base substrate; and a second electrode at a side of the light-emitting layer away from the first electrode. The display substrate further includes a reflection layer between the first electrode and the base substrate, the first electrode is insulated from the reflection layer, and the first electrode is coupled to the pixel circuitry through a via hole penetrating through the reflection layer.

In the embodiments of the present disclosure, the reflection layer independent of the first electrode is arranged between the first electrode and the base substrate. In this way, the design of the reflection layer is not limited by the first electrode, and the reflection layer is provided with a large area, so it is able to increase the reflectivity of the reflection layer and enhance a resonant cavity effect of the display substrate, thereby to improve the luminous efficiency and the display brightness of the display device.

The first electrode is one of an anode and a cathode, and the second electrode is the other one of the anode and the cathode. The display substrate is a silicon-based display substrate, and the base substrate is a silicon base substrate.

The base substrate includes the pixel circuitry formed on the substrate. The pixel circuitry includes a driving transistor which includes a source electrode, a drain electrode and a gate electrode. The drain electrode of the driving transistor is coupled to the first electrode through the pixel circuitry and the via hole 02, so as to drive the OLED element to emit light.

In some embodiments of the present disclosure, a minimum distance between the via holes of the adjacent pixel units is greater than a minimum distance between the first electrodes of the adjacent pixel units.

In some embodiments of the present disclosure, a minimum distance between an orthogonal projection of the via hole onto the first electrode and an edge of the first electrode is D1, a distance between the orthogonal projection of the via hole onto the first electrode and a center of the first electrode is D2, and D1 is less than D2.

In some embodiments of the present disclosure, the reflection layers of different pixel units are connected to form one piece. In this way, in the display substrate, the reflection layers are continuous and the reflective area is increased, so it is able to increase the reflectivity of the reflection layer and enhance the resonant cavity effect of the display substrate, thereby to improve the luminous efficiency and the display brightness of the display device.

In some embodiments of the present disclosure, a ratio of an area of the reflection layer to an area of a display region of the display substrate is greater than 90%, so as to ensure the reflectivity of the reflection layer.

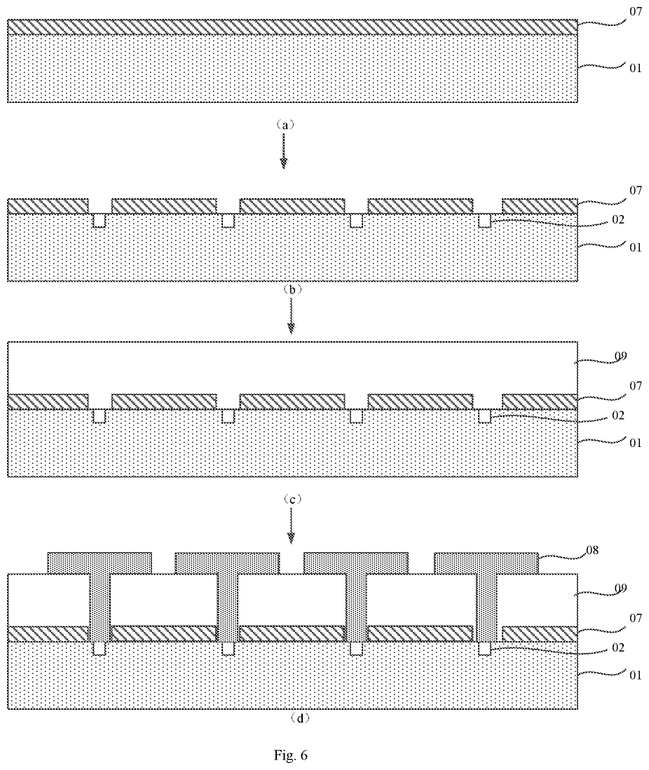

In some embodiments of the present disclosure, as shown in FIGS. 5 and 6, the display substrate includes a base substrate 01, a via hole 02 penetrating through the base substrate 01, a reflection layer 07 on the base substrate 01, an insulation layer 09, and a first electrode 08 on the insulation layer 09. The reflection layer 07A is a conductive reflection layer, e.g., it is made of a metal with good reflectivity, such as Al or Ag. The reflection layer 07 is continuous at the display region of the display substrate, and in order to prevent the first electrodes 08 of the adjacent sub-pixels are electrically coupled to each other through the reflection layer 07, the insulation layer 09 is provided between the reflection layer 07 and the first electrode 08. The insulation layer 09 is made of an inorganic insulating material, such as silicon oxide, silicon nitride, etc. A thickness of the insulation layer 09 depends on a cavity length of the microcavity, e.g., 400 Å to 1000 Å, so as to ensure the microcavity effect.

A via hole is formed in the reflection layer 07 to expose the via hole 02, so as to prevent the reflection layer 07 from being electrically coupled to the first electrode 08. A size of the via hole in the reflection layer 07 depends on a size of the via hole 02, and it may be slightly larger than the size of the via hole 02. In some embodiments of the present disclosure, a cross section of the via hole in the reflection layer 07 in a direction parallel to the base substrate 01 has a size of 0.6 μm*0.6 μm.

A via hole is formed in the insulation layer 09 to expose the via hole 02, so that the first electrode 08 is electrically coupled to the pixel circuitry through the via hole 02. At the same time, the via hole in the insulation layer 09 encloses the cross section of the reflection layer 07, so that the reflection layer 07 is insulated from the first electrode 08. A size of the via hole in the insulation layer 09 depends on the size of the via hole 02, and it may be slightly larger than the size of the via hole 02. In some embodiments of the present disclosure, a cross section of the via hole in the insulation layer 09 in a direction parallel to the base substrate 01 has a size of 0.4 μm*0.4 μm.

The first electrode 08 is made of a transparent conductive material, such as ITO, and it has a thickness of 500 Å to 1200 Å. The first electrode 08 is coupled to the pixel circuitry through the via hole in the insulation layer 09 and the via hole 02.

In the embodiments of the present disclosure, the ratio of the area of the reflection layer 07 to the area of the display region of the display substrate is up to 1−0.6*0.6/((1.7−0.4)*(5.1−0.4))=92.6%, i.e., a ratio of an area of the reflective surface is increased remarkably. In this way, it is able to enhance the resonant cavity effect of the display substrate, thereby to improve the luminous efficiency and the display brightness of the display device.

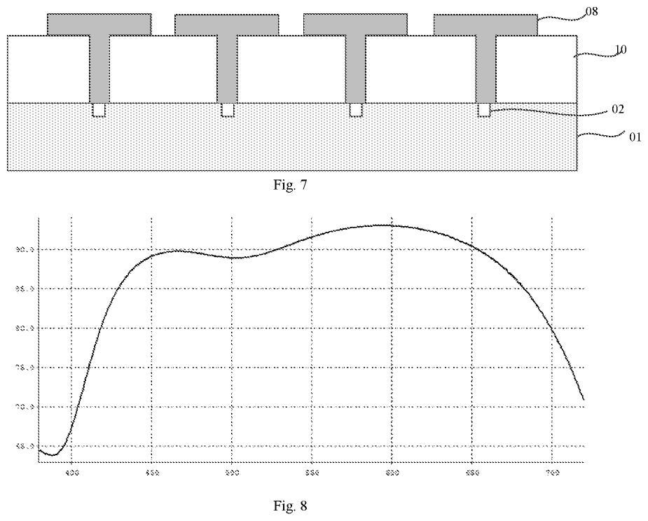

In some embodiments of the present disclosure, the reflection layer is an insulation reflection layer, so as to form the first electrode directly on the reflection layer without any insulation layer between the reflection layer and the first electrode, thereby to simplify the structure and the manufacture of the display substrate. As shown in FIG. 7, the display substrate includes a base substrate 01, a via hole 02 penetrating through the base substrate 01, an insulation reflection layer 10 on the base substrate 01, and a first electrode 08 on the insulation reflection layer 10.

The insulation reflection layer 10 adopts a Distributed Bragg Reflection (DBR) structure. The DBR structure is a periodic structure including two material layers with different refractive indexes laminated alternately one on another, and an optical thickness of each layer is ¼ of a central reflection wavelength. The DBR structure is equivalent to a set of photonic crystals. Since it is impossible for an electromagnetic wave at a frequency which falls within an energy gap to pass through the DBR structure, the reflectivity of the DBR structure is more than 99%.

A via hole is formed in the insulation reflection layer 10 to expose the via hole 02, so that the first electrode 08 is coupled to the pixel circuitry through the via hole 02. A size of the via hole in the insulation reflection layer 10 depends on a size of the via hole 02, and it is slightly larger than the size of the via hole 02. In some embodiments of the present disclosure, a cross section of the via hole in the insulation reflection layer 10 in a direction parallel to the base substrate 01 has a size of 0.4 μm*0.4 μm.

The first electrode 08 is made of a transparent conductive material, such as ITO, and it has a thickness of 500 Å to 1200 Å. The first electrode 08 is coupled to the pixel circuitry through the via hole in the insulation layer 09 and the via hole 02.

In the embodiments of the present disclosure, a ratio of an area of the insulation reflection layer 10 to the area of the display region of the display substrate is more than 93%. In this way, it is able to remarkably increase a ratio of an area of the reflective surface, and enhance the resonant cavity effect of the display substrate, thereby to improve the luminous efficiency and the display brightness of the display device.

In some embodiments of the present disclosure, the insulation reflection layer 10 includes at least one silicon dioxide film layer and at least one silicon nitride film layer, and the silicon dioxide film layers and the silicon nitride film layers are alternately laminated one on another to form the DBR structure.

Specifically, the insulation reflection layer includes three silicon dioxide film layers and three silicon nitride film layers, and the silicon dioxide film layers and the silicon nitride film layers are designed according to the required reflectivity. Of course, the quantity of silicon dioxide film layers and silicon nitride film layers in the insulation reflection layer will not be particularly defined herein.

For example, a thickness of a first silicon dioxide film layer is 86.68 nm, a thickness of a first silicon nitride film layer is 63.84 nm, a thickness of a second silicon dioxide film layer is 87.91 nm, a thickness of a second silicon nitride film layer is 60.83 nm, a thickness of a third silicon dioxide film layer is 145.55 nm, and a thickness of a third silicon nitride film layer is 97.09 nm. FIG. 8 shows a curve of the reflectivity of the insulation reflection layer 10 with this structure, where an ordinate is the reflectivity, and an abscissa is a wavelength of the reflected light in unit of nm. As shown in FIG. 8, the average reflectivity of the insulation reflection layer 10 to light at a wavelength of 400 nm to 700 nm is greater than 80%. As a result, it is able to effectively enhance the resonant cavity effect of the display substrate, thereby to improve the luminous efficiency and the display brightness of the display device.

The present disclosure further provides in some embodiments a display device including the above-mentioned display substrate and a driving circuitry for driving the display substrate.

The display device may include, but not limited to, a radio frequency unit, a network module, an audio output unit, an input unit, a sensor, a display unit, a user input unit, an interface unit, a memory, a processor, and a power source. It should be appreciated that, the display device may not be limited thereto, i.e., it may include more or fewer members, or some members may be combined, or the members may be arranged in different modes. In the embodiments of the present disclosure, the display device may include, but not limited to, display, mobile phone, flat-panel computer, television, wearable electronic device or navigator.

The display device may be any product or member having a display function, e.g., television, display, digital photo frame, mobile phone or tablet computer. The display device further includes a flexible circuit board, a printed circuited board and a back plate.

The present disclosure further provides in some embodiments a method for manufacturing a display substrate. The display substrate includes a base substrate and pixel units arranged in an array form on the base substrate, and the base substrate includes a pixel circuitry formed on a substrate. The method includes: providing the base substrate: forming a first electrode on the base substrate: forming a light-emitting layer at a side of the first electrode away from the base substrate: and forming a second electrode at a side of the light-emitting layer away from the first electrode. The method further includes forming a reflection layer between the first electrode and the base substrate, the first electrode is insulated from the reflection layer, and the first electrode is coupled to the pixel circuitry through a via hole penetrating through the reflection layer.

In the embodiments of the present disclosure, the reflection layer independent of the first electrode is arranged between the first electrode and the base substrate. In this way, the design of the reflection layer is not limited by the first electrode, and the reflection layer is provided with a large area, so it is able to increase the reflectivity of the reflection layer and enhance a resonant cavity effect of the display substrate, thereby to improve the luminous efficiency and the display brightness of the display device.

The first electrode is one of an anode and a cathode, and the second electrode is the other one of the anode and the cathode. The display substrate is a silicon-based display substrate, and the base substrate is a silicon base substrate.

The base substrate includes the pixel circuitry formed on the substrate. The pixel circuitry includes a driving transistor which includes a source electrode, a drain electrode and a gate electrode. The drain electrode of the driving transistor is coupled to the first electrode through the pixel circuitry and the via hole 02, so as to drive the OLED element to emit light.

In some embodiments of the present disclosure, the reflection layer is a conductive reflection layer, and the method further includes forming an insulation layer between the conductive reflection layer and the first electrode.

As shown in FIG. 6, in the embodiments of the present disclosure, the method includes the following steps.
Step a: a base substrate 01 is provided, and a reflection layer 07 is deposited on the base substrate 01. The reflection layer 07 is made of Al or Ag with a good light reflection property.
Step b: the reflection layer 07 is etched to form a via hole to expose the via hole 02, so as to prevent the reflection layer 07 from being electrically coupled to the first electrode 08. A size of the via hole in the reflection layer 07 depends on a size of the via hole 02, and it may be slightly larger than the size of the via hole 02. In some embodiments of the present disclosure, a cross section of the via hole in the reflection layer 07 in a direction parallel to the base substrate 01 has a size of 0.6 μm*0.6 μm.
Step c: an inorganic insulation layer material is deposited to form an insulation layer 09, so as to separate the first electrode 08 from the reflection layer 07. The insulation layer 09 is made of an inorganic insulating material, such as silicon oxide, silicon nitride, etc. A thickness of the insulation layer 09 depends on a cavity length of the microcavity, e.g., 400 Å to 1000 Å, so as to ensure the microcavity effect.
Step d: the reflection layer 09 is etched to form a via hole to expose the via hole 02, so that the first electrode 08 is electrically coupled to the pixel circuitry through the via hole 02. At the same time, the via hole in the insulation layer 09 encloses the cross section of the reflection layer 07, so that the reflection layer 07 is insulated from the first electrode 08. A size of the via hole in the insulation layer 09 depends on the size of the via hole 02, and it may be slightly larger than the size of the via hole 02. In some embodiments of the present disclosure, a cross section of the via hole in the insulation layer 09 in a direction parallel to the base substrate 01 has a size of 0.4 μm*0.4 μm.

A transparent conductive material is deposited on the insulation layer 09, and then patterned to form the first electrode 08 having a thickness of 500 Å to 1200 Å. The first electrode 08 is coupled to the pixel circuitry through the via hole in the insulation layer 09 and the via hole 02.

In the embodiments of the present disclosure, the ratio of the area of the reflection layer 07 to the area of the display region of the display substrate is up to 1−0.6*0.6/((1.7−0.4)*(5.1−0.4))=92.6%, i.e., a ratio of an area of the reflective surface is increased remarkably. In this way, it is able to enhance the resonant cavity effect of the display substrate, thereby to improve the luminous efficiency and the display brightness of the display device.

In some embodiments of the present disclosure, the reflection layer is an insulation reflection layer, so as to form the first electrode directly on the reflection layer without any insulation layer between the reflection layer and the first electrode, thereby to simplify the structure and the manufacture of the display substrate. As shown in FIG. 7, the display substrate includes a base substrate 01, a via hole 02 penetrating through the base substrate 01, an insulation reflection layer 10 on the base substrate 01, and a first electrode 08 on the insulation reflection layer 10.

The insulation reflection layer 10 adopts a DBR structure. The DBR structure is a periodic structure including two material layers with different refractive indexes laminated alternately one on another, and an optical thickness of each layer is ¼ of a central reflection wavelength. The DBR structure is equivalent to a set of photonic crystals. Since it is impossible for an electromagnetic wave at a frequency which falls within an energy gap to pass through the DBR structure, the reflectivity of the DBR structure is more than 99%.

In some embodiments of the present disclosure, the forming the reflection layer includes forming at least one silicon dioxide film layer and at least one silicon nitride film layer. The silicon dioxide film layers and the silicon nitride film layers are laminated alternately one on another to form the DBR structure.

Specifically, the insulation reflection layer includes three silicon dioxide film layers and three silicon nitride film layers, and the silicon dioxide film layers and the silicon nitride film layers are designed according to the required reflectivity. Of course, the quantity of silicon dioxide film layers and silicon nitride film layers in the insulation reflection layer will not be particularly defined herein.

For example, a thickness of a first silicon dioxide film layer is 86.68 nm, a thickness of a first silicon nitride film layer is 63.84 nm, a thickness of a second silicon dioxide film layer is 87.91 nm, a thickness of a second silicon nitride film layer is 60.83 nm, a thickness of a third silicon dioxide film layer is 145.55 nm, and a thickness of a third silicon nitride film layer is 97.09 nm. FIG. 8 shows a curve of the reflectivity of the insulation reflection layer 10 with this structure, where an ordinate is the reflectivity, and an abscissa is a wavelength of the reflected light in unit of nm. As shown in FIG. 8, the average reflectivity of the insulation reflection layer 10 to light at a wavelength of 400 nm to 700 nm is greater than 80%. As a result, it is able to effectively enhance the resonant cavity effect of the display substrate, thereby to improve the luminous efficiency and the display brightness of the display device.

It should be appreciated that, the above embodiments have been described in a progressive manner, and the same or similar contents in the embodiments have not been repeated, i.e., each embodiment has merely focused on the difference from the others. Especially, the method embodiments are substantially similar to the product embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a base substrate and pixel units arranged in an array form on the base substrate, the base substrate comprising a pixel circuitry formed on a substrate, wherein each pixel unit comprises:
a first electrode at a side of the base substrate;
a light-emitting layer at a side of the first electrode away from the base substrate; and
a second electrode at a side of the light-emitting layer away from the first electrode,
wherein the display substrate further comprises a reflection layer between the first electrode and the base substrate, the first electrode is insulated from the reflection layer, and the first electrode is coupled to the pixel circuitry through a via hole penetrating through the reflection layer.

2. The display substrate according to claim 1, wherein a minimum distance between the via holes of the adjacent pixel units is greater than a minimum distance between the first electrodes of the adjacent pixel units.

3. The display substrate according to claim 1, wherein a minimum distance between an orthogonal projection of the via hole onto the first electrode and an edge of the first electrode is D1, a distance between the orthogonal projection of the via hole onto the first electrode and a center of the first electrode is D2, and D1 is less than D2.

4. The display substrate according to claim 1, wherein the reflection layers of different pixel units are connected to form one piece.

5. The display substrate according to claim 1, wherein a ratio of an area of the reflection layer to an area of a display region of the display substrate is greater than 90%.

6. The display substrate according to claim 1, wherein the reflection layer is a conductive reflection layer, and an insulation layer is arranged between the conductive reflection layer and the first electrode.

7. The display substrate according to claim 6, wherein the insulation layer has a thickness of 400 Å to 1000 Å.

8. The display substrate according to claim 1, wherein the reflection layer is an insulation reflection layer, the insulation reflection layer comprises at least one silicon dioxide film layer and at least one silicon nitride film layer, and the silicon dioxide film layers and the silicon nitride film layers are alternately laminated one on another.

9. The display substrate according to claim 8, wherein the insulation reflection layer comprises three silicon dioxide film layers and three silicon nitride film layers, and a reflectivity of the insulation reflection layer to light at a wavelength of 400 nm to 700 nm is greater than 80%.

10. The display substrate according to claim 1, wherein the first electrode has a thickness of 500 Å to 1200 Å.

11. A display device, comprising the display substrate of claim 1 and a driving circuitry for driving the display substrate.

12. A method for manufacturing a display substrate, the display substrate comprising a base substrate and pixel units arranged in an array form on the base substrate, the base substrate comprising a pixel circuitry formed on a substrate, wherein the method comprises:
providing the base substrate; forming a first electrode on the base substrate;
forming a light-emitting layer at a side of the first electrode away from the base substrate; and
forming a second electrode at a side of the light-emitting layer away from the first electrode,
wherein the method further comprises forming a reflection layer between the first electrode and the base substrate, the first electrode is insulated from the reflection layer, and the first electrode is coupled to the pixel circuitry through a via hole penetrating through the reflection layer.

13. The method according to claim 12, wherein the reflection layer is a conductive reflection layer, and the method further comprises forming an insulation layer between the conductive reflection layer and the first electrode.

14. The method according to claim 12, wherein the reflection layer is an insulation reflection layer, the forming the reflection layer comprises forming at least one silicon dioxide film layer and at least one silicon nitride film layer, and the silicon dioxide film layers and the silicon nitride film layers are alternately laminated one on another.

15. The display substrate according to claim 2, wherein a minimum distance between an orthogonal projection of the via hole onto the first electrode and an edge of the first electrode is D1, a distance between the orthogonal projection of the via hole onto the first electrode and a center of the first electrode is D2, and D1 is less than D2.

16. The display substrate according to claim 2, wherein a ratio of an area of the reflection layer to an area of a display region of the display substrate is greater than 90%.

17. The display substrate according to claim 3, wherein a ratio of an area of the reflection layer to an area of a display region of the display substrate is greater than 90%.

18. The display substrate according to claim 4, wherein a ratio of an area of the reflection layer to an area of a display region of the display substrate is greater than 90%.

19. The display device according to claim 11, wherein a minimum distance between the via holes of the adjacent pixel units is greater than a minimum distance between the first electrodes of the adjacent pixel units.

20. The display device according to claim 11, wherein a minimum distance between an orthogonal projection of the via hole onto the first electrode and an edge of the first electrode is D1, a distance between the orthogonal projection of the via hole onto the first electrode and a center of the first electrode is D2, and D1 is less than D2.
